(19) United States
(12) Patent Application Publication
(10) Pub. No.: US 2014/0326016 A1
(43) Pub. Date: Nov. 6, 2014

(54) COOLING DEVICE AND ELECTRIC EQUIPMENT USING THE SAME

(71) Applicant: NEC Corporation, Tokyo (JP)

(72) Inventors: Akira Shoujiguchi, Tokyo (JP); Minoru Yoshikawa, Tokyo (JP); Hitoshi Sakamoto, Tokyo (JP); Masaki Chiba, Tokyo (JP); Kenichi Inaba, Tokyo (JP); Arihiro Matsunaga, Tokyo (JP)

(21) Appl. No.: 14/370,194

(22) PCT Filed: Dec. 21, 2012
(86) PCT No.: PCT/JP2012/008208

§ 371 Date: Jul. 1, 2014

(30) Foreign Application Priority Data
Jan. 1, 2012 (JP) 2012-000077

(51) Int. Cl. H05K 7/20; F25B 39/00

(52) U.S. Cl. CPC H05K 7/208; F25B 39/00; H05K 7/20309; H05K 7/20318
USPC 62/428; 62/513

(57) ABSTRACT

A cooling device of the present invention is a cooling device arranged in a chassis equipped with an upper surface, and comprises: a refrigerant; a vaporizer that includes an evaporative vessel having a side face of a curved surface shape, and performs heat-absorption by making the refrigerant change its phase from a liquid phase state to a vapor phase state; a condenser that performs heat-radiation by making the refrigerant change its phase from a vapor phase state to a liquid phase state; a pipe that connects the vaporizer and the condenser; and a flow path suppression means for suppressing a cooling wind that flows between an area over the evaporative vessel and the upper surface.

### TECHNICAL FIELD

The present invention relates to a cooling device which cools a heat generating member in electronic equipment and an electronic equipment using the same, and, more particularly, to a cooling device which cools a heat generating member using phase changes of a refrigerant in electronic equipment of a low height such as a 1U server and an electronic equipment using the same.

### BACKGROUND ART

In recent years, along with improvement in performance, functions and the like of a semiconductor device and electronic equipment, their heat generation amounts have been also increasing. For example, also in a small electronic device such as a personal computer and a 1U server, a heat generation amount from a semiconductor element such as a CPU is being increased along with increase in an amount of information and a processing speed. There are arranged a plurality of cooling fans or a large cooling fan in a personal computer and a 1U server because the semiconductor element may be damaged by heat radiated from the semiconductor element itself. The 1U server is a server housed in a rack of 1U (1.75 inches) which is the minimum unit of a rack height set by Electronic Industries Alliance.

In a small electronic device such as a personal computer and a 1U server, miniaturization of a cooling device, especially keeping a height low, is required because a mounting space cannot be secured sufficiently. Accordingly, instead of arranging a plurality of cooling fans or a large cooling fan, arranging a cooling device of a refrigerant circulation type has been proposed.

In patent literature 1, there is disclosed electronic equipment equipped with a refrigerant circulation type cooling device. In electronic equipment of patent literature 1, a cooling device, where a vaporizer and a condenser which cool the CPU are connected by pipes, a cooling device vaporizes a refrigerant by heat from the CPU and condenses it by cooling the condenser by using a fan. Then, the cooling device performs transportation and heat radiation of heat generated by a CPU. In this electronic equipment, it is enabled to mount a cooling device into thin type electronic equipment by dividing the condenser of the cooling device into a main condenser and an associate condenser and installing the associate condenser on the vaporizer.

In patent literature 2, there is disclosed electronic equipment which cools a CPU using a cooling device of a refrigerant circulation type and cools other heat generating members using a cooling wind from a fan. It is said that a cooling device in patent literature 2 improves the performance of a condenser by touching with a high temperature-side pipe and a low temperature-side pipe, which are connecting between the condenser and a vaporizer, each other via a thermal joint.

### PRIOR ART DOCUMENT

### Patent Literature

Patent literature 1: Japanese Patent Application Laid-Open No. 2006-012875
Patent literature 2: Japanese Patent Application Laid-Open No. 2007-010211

### BRIEF SUMMARY OF THE INVENTION

### Problems to be Solved by the Invention

However, a cooling device in patent literature 1 cannot cool an associate condenser sufficiently because the distance between the associate condenser arranged on a vaporizer and a fan becomes large. In this case, the cooling efficiency of a cooling device declines. In addition, in a cooling device in patent literature 2, because a vaporizer is arranged in order to cool a CPU, a flow of a cooling wind delivered from a fan is disturbed by the vaporizer. Accordingly, the cooling efficiency for other heat generating members besides the CPU declines, and the cooling efficiency of electronic equipment as a whole declines consequently.

On the other hand, when, in electronic equipment of an existing air cooling system, a cooling device of a refrigerant circulation type is arranged instead of arranging a plurality of cooling fans or a large cooling fan, a layout change of each component in the electronic equipment is needed to be performed to optimize a flow of a cooling wind. However, it is difficult to perform a layout of components again for each model of electronic equipment.

Thus, in cooling devices disclosed in a patent literature 1 and a patent literature 2, there is a problem that the cooling efficiency of electronic equipment as a whole falls when a cooling device of a refrigerant circulation type is mounted on thin type electronic equipment. Further, in electronic equipment of an existing air cooling system, when a cooling device of a refrigerant circulation type is arranged instead of arranging a plurality of cooling fans or a large cooling fan, there is a problem that a layout change of each component in the electronic equipment is needed to optimize a flow of a cooling wind.

An object of the present invention is to provide a cooling device and electronic equipment using the same which settle a problem, which is the problem mentioned above, that the cooling efficiency of electronic equipment as a whole declines when a cooling device of a refrigerant circulation type is arranged in thin type electronic equipment, and that a layout change of each component in the electronic equipment is required to avoid that.

### Means for Solving the Problems

In order to achieve the above-mentioned object, a cooling device according to the present invention is a cooling device that is arranged in a chassis having an upper surface, and comprises: a refrigerant; a vaporizer including an evaporative vessel having a side face of a curved surface shape, and performing heat-absorption by making the refrigerant change a phase from a liquid phase state to a vapor phase state; a condenser to perform heat-radiation by making the refrigerant change a phase from a vapor phase state to a liquid phase state; a pipe to connect the vaporizer and the condenser; and a flow path suppression means for suppressing a cooling wind flowing between an area over the evaporative vessel and the upper surface.

In order to achieve the above-mentioned object, electronic equipment according to the present invention comprises: a chassis having an upper surface; the cooling device mentioned above; a first heat generating member and a second heat generating member, both generating heat along with their operations; a fan being arranged facing said condenser of the cooling device which delivers a cooling wind. Here, the first heat generating member is arranged in an area under the evaporative vessel; and the second heat generating member is arranged in a direction along a curved-surface-shape side face of the evaporative vessel.

### Effect of the Invention

A cooling device according to the present invention and electronic equipment using the same can improve, when a cooling device of a refrigerant circulation type is arranged in thin type electronic equipment, the cooling efficiency of the electronic equipment as a whole without changing the layout of each component in the electronic equipment.

### BRIEF DESCRIPTION OF THE DRAWINGS

FIG. 1A is a top view showing an internal configuration of electronic equipment 10 according to a first exemplary embodiment of the present invention.

FIG. 1B is a side view showing an internal configuration of the electronic equipment 10 according to the first exemplary embodiment of the present invention.

FIG. 1C is a perspective side view of 20 of a cooling device according to the first exemplary embodiment of the present invention.

FIG. 2A is a top view showing an internal configuration of an electronic equipment 90 of an air cooling system.

FIG. 2B is a side view showing an internal configuration of the electronic equipment 90 of an air cooling system.

FIG. 3 is a top view showing an internal configuration of a server 100 according to a second exemplary embodiment of the present invention.

FIG. 4 is a top view showing an internal configuration of a related server 900 of an air cooling system.

FIG. 5A is a top view showing part of an internal configuration of the server 100 according to the second exemplary embodiment of the present invention.

FIG. 5B is a perspective side view showing a part of an internal configuration of the server 100 according to the second exemplary embodiment of the present invention.

FIG. 6A is a top view showing part of an internal configuration of a server 100B according to a modified example of the second exemplary embodiment of the present invention.

FIG. 6B is a top view showing part of an internal configuration of a server 100C according to a modified example of the second exemplary embodiment of the present invention.

FIG. 6C is a top view showing part of an internal configuration of a server 100D according to a modified example of the second exemplary embodiment of the present invention.

FIG. 7A is a top view showing part of an internal configuration of a server 200 according to a third exemplary embodiment of the present invention.

FIG. 7B is a perspective side view showing part of an internal configuration of the server 200 according to the third exemplary embodiment of the present invention.

FIG. 8A is a top view showing part of an internal configuration of a server 200B according to a modified example of the third exemplary embodiment of the present invention.

FIG. 8B perspective side view showing part of an internal configuration of the server 200B according to a modified example of the third exemplary embodiment of the present invention.

FIG. 9A is a top view showing part of an internal configuration of a server 300 according to a fourth exemplary embodiment of the present invention.

FIG. 9B is a perspective side view showing part of an internal configuration of the server 300 according to the fourth exemplary embodiment of the present invention.

FIG. 10A is a top view showing part of an internal configuration of a server 300B according to a modified example of the fourth exemplary embodiment of the present invention.

FIG. 10B is a perspective side view showing part of an internal configuration of the server 300B according to a modified example of the fourth exemplary embodiment of the present invention.

### MODE FOR CARRYING OUT THE INVENTION

### First Exemplary Embodiment

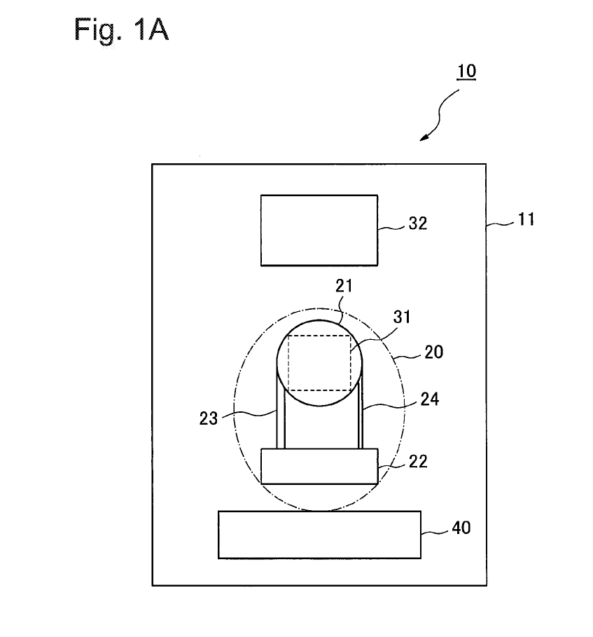

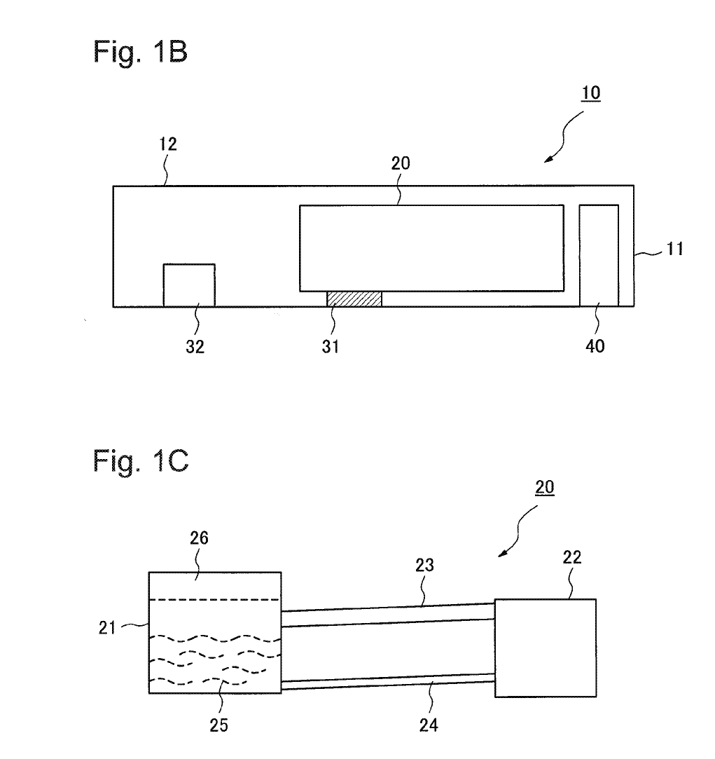

The first exemplary embodiment will be described. There is shown a top view indicating an internal configuration of electronic equipment according to this exemplary embodiment in FIG. 1A, and a side view in FIG. 1B. FIG. 1C shows a perspective side view of a cooling device according to this exemplary embodiment. In FIG. 1A and FIG. 1B, the electronic equipment 10 according to this exemplary embodiment includes a low-height chassis 11 having an upper surface 12. There are arranged in the chassis 11 of the electronic equipment 10 a cooling device 20 of a phase change cooling system, a first heat generating member 31, a second heat generating member 32, a fan 40 and other electronic components which are not illustrated. In FIG. 1A and FIG. 1C, the cooling device 20 according to this exemplary embodiment includes a vaporizer 21, a condenser 22, a steam pipe 23, a liquid pipe 24, a refrigerant 25 and a flow path suppression means 26.

In the chassis 11, the first heat generating member 31 is arranged under the vaporizer 21 of the cooling device 20, and the condenser 22 is arranged facing the fan 40. The vaporizer 21 is arranged between the second heat generating member 32 and the condenser 22. The first heat generating member 31 is cooled by the cooling device 20, and the condenser 22 and the second heat generating member 32 are cooled by the fan 40. Description will be made later about cooling of the second heat generating member 32.

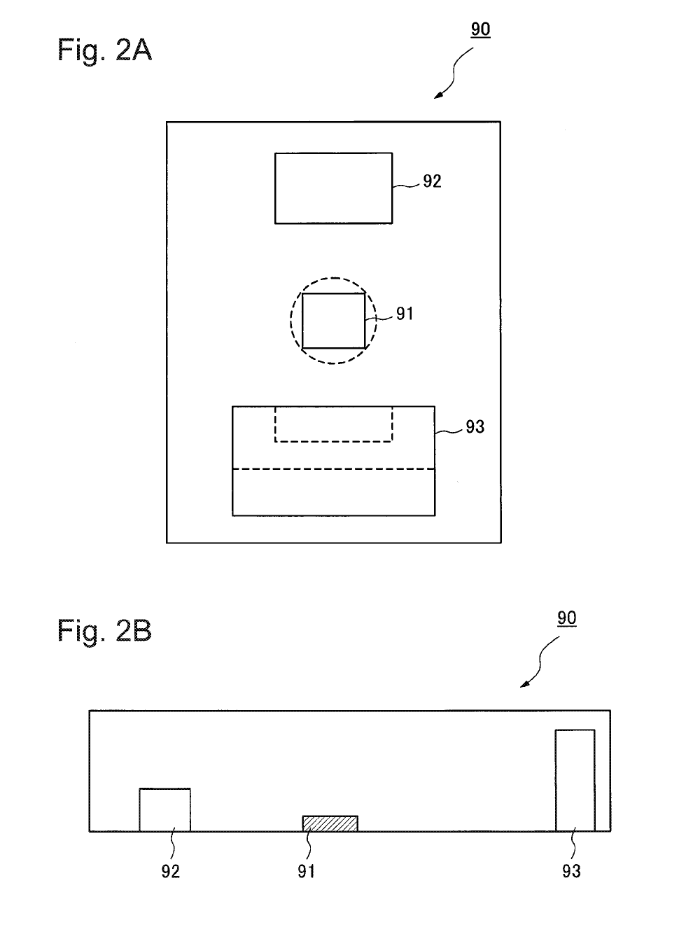

Here, a top view showing an internal configuration of related electronic equipment to which an air cooling system is applied is indicated in FIG. 2A, and a side view in FIG. 2B. In FIG. 2A and FIG. 2B, the related electronic equipment 90 to which an air cooling system is applied includes a first heat generating member 91, a second heat generating member 92, a fan 93 and other electronic components which are not illustrated. In the related electronic equipment 90 of FIG. 2, the first heat generating member 91 and the second heat generating member 92 are cooled by a cooling wind delivered from the fan 93. Here, in order to improve a cooling capacity, the large fan 93 is arranged in the related electronic equipment 90 of an air cooling system. Meanwhile, a heat sink and the like may be arranged on the heat generating members.

When the electronic equipment 10 having the cooling device 20 of a phase change cooling system shown in FIGS. 1A-1C and the air cooling type electronic equipment 90 shown in FIGS. 2A-2B are compared, the electronic equipment 10 shown in FIGS. 1A-1C is obtained by arranging, in the electronic equipment 90 shown in FIG. 2, the condenser 22 in a space that becomes available by substituting the small fan 40 for the large fan 93, and arranging the vaporizer 21 in a position over the first heat generating member 91.

That is, about the cooling device 20 and the electronic equipment 10 according to this exemplary embodiment, a change to the electronic equipment 10 of a phase change cooling system from the related electronic equipment 90 of an air cooling system is made by just arranging the condenser 22 in part of the fan arrangement area in the related electronic equipment 90 of an air cooling system without performing other large layout changes.

Next, a cooling efficiency of the electronic equipment 10 equipped with the cooling device 20 according this exemplary embodiment will be described by explaining each element of the cooling device 20.

The vaporizer 21 is arranged on the first heat generating member 31, and cools the first heat generating member 31 by making heat of the first heat generating member 31 be absorbed by the refrigerant 25 of a liquid phase state that is collected in the interior. In this exemplary embodiment, the side face of an evaporative vessel which constitutes the vaporizer 21 is formed into a curved surface shape. For example, the side face of an evaporative vessel is formed into a shape that widens smoothly once from the windward direction of a cooling wind delivered from the fan 40 toward predetermined directions and then narrows smoothly. By composing the side face of an evaporative vessel in a curved surface shape, a cooling wind which is delivered from the fan 40 and reaches the vaporizer 21 experiences a small occurrence of detachment of a flow from the side face of the evaporative vessel and a turbulent flow, and has a small decrease of a wind velocity even after flowing into the side behind the vaporizer 21 along the side face of the evaporative vessel.

The condenser 22 cools the refrigerant 25 of a vapor phase state. For example, the condenser 22 has a plurality of tubular bodies that are not illustrated and radiators arranged along the lengthwise direction of the tubular bodies. The condenser 22 makes heat of the refrigerant 25 of the vapor phase state be radiated to outside air via the radiators by the refrigerant 25 of the vapor phase state passing interior of the tubular bodies. Meanwhile, in this exemplary embodiment, the condenser 22 employs a plate-like fin of metal as a radiator.

The steam pipe 23 connects the vaporizer 21 and the condenser 22. The refrigerant 25 that has become a vapor phase state in the vaporizer 21 passes the steam pipe 23, and is transported to the condenser 22.

The liquid pipe 24 connects the condenser 22 and the vaporizer 21. The refrigerant 25 that has become a liquid phase state in the condenser 22 passes the liquid pipe 24, and is transported to the vaporizer 21.

The refrigerant 25 is a medium having a low-boiling point. The refrigerant 25 absorbs heat of the first heat generating member 31 in the vaporizer 21, and changes its phase to the vapor phase state from the liquid phase state. The refrigerant 25 of the vapor phase state is transported to the condenser 22 via the steam pipe 23. In the condenser 22, the refrigerant 25 condenses by radiating heat into outside air and changes its phase to the liquid phase state from the vapor phase state. The refrigerant 25 of the liquid phase state is transported to the vaporizer 21 again via the liquid pipe 24.

The flow path suppression means 26 is arranged in a manner reaching near the upper surface 12 of the chassis 11, and suppresses leak of a cooling wind, which has been delivered from the fan 40, passed the condenser 22 and reached the vaporizer 21, through a space over the vaporizer 21. By having the flow path suppression means 26, a cooling wind which has reached a vaporizer 11 flows toward the backward along the side face of the evaporative vessel without passing the space over the evaporative vessel. By this, at the back of the evaporative vessel, a cooling wind having a maintained wind speed can be obtained in the neighborhood of the substrate surface.

The flow path suppression means 26 can be configured by, when the evaporative vessel is arranged on the first heat generating member 31, forming the height of the evaporative vessel which constitutes the vaporizer 21 as a height that the upper surface of the evaporative vessel reaches near the upper surface 12 of the chassis 11, for example. The flow path suppression means 26 can be also configured by a flow path suppression member arranged on the evaporative vessel. This flow path suppression member is formed with a height that the upper surface of the flow path suppression member reaches near the upper surface 12 of the chassis 11 when arranging the evaporative vessel on the first heat generating member 31 and arranging the flow path suppression member on the evaporative vessel. Alternatively, the flow path suppression member can be configured by providing a cap for the vaporizer on the lid of the upper chassis side.

The cooling device 20 constituted as above makes the refrigerant 25 keep circulating in the cooling device 20 without using a liquid pump and the like, and radiates heat which has been generated by the first heat generating member 31 to outside air, cooling the first heat generating member 31.

Further, in the cooling device 20 constituted as above, the flow path suppression means 26 prevents a cooling wind which has reached the vaporizer 21 from flowing through the space over the vaporizer 21, and the side face of an evaporative vessel which constitutes the vaporizer 21 is formed into a curved surface shape such as a shape that widens smoothly once to predetermined directions from the windward direction of the cooling wind delivered from the fan 40 and then narrows smoothly. In this case, because there is a small occurrence of detachment and a turbulent flow of a flow from the side face of the evaporative vessel, a cooling wind delivered from the fan 40 flows into the backward along the side face while keeping a wind speed, and cools the second heat generating member 32 arranged behind the vaporizer 21. Accordingly, even when the cooling device 20 according to this exemplary embodiment is mounted on thin type electronic equipment, the cooling efficiency of the whole electronic equipment can be improved.

As above, the cooling device 20 according to this exemplary embodiment and the electronic equipment 10 using that can improve, when the cooling device 20 of a refrigerant circulation type is arranged in thin type electronic equipment, the cooling efficiency of the electronic equipment 10 as a whole without changing the layout of each component in the electronic equipment 10.

### Second Exemplary Embodiment

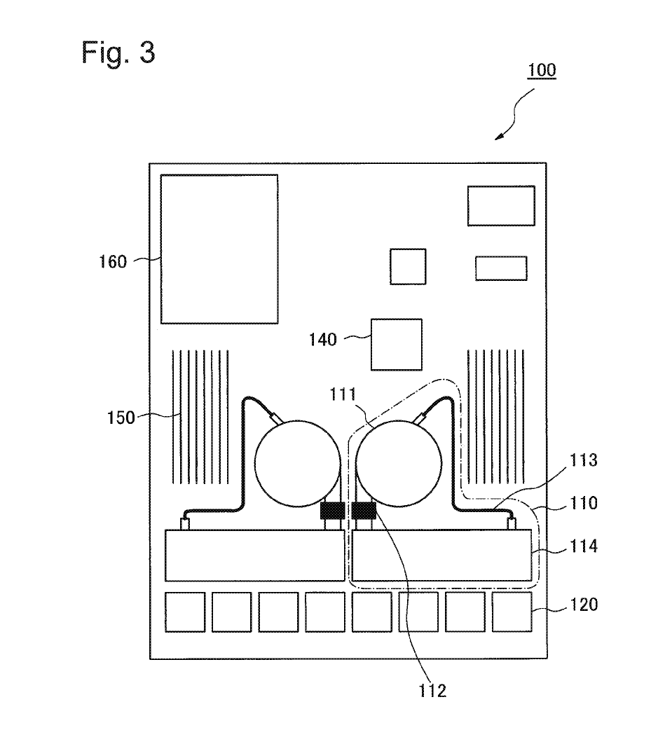

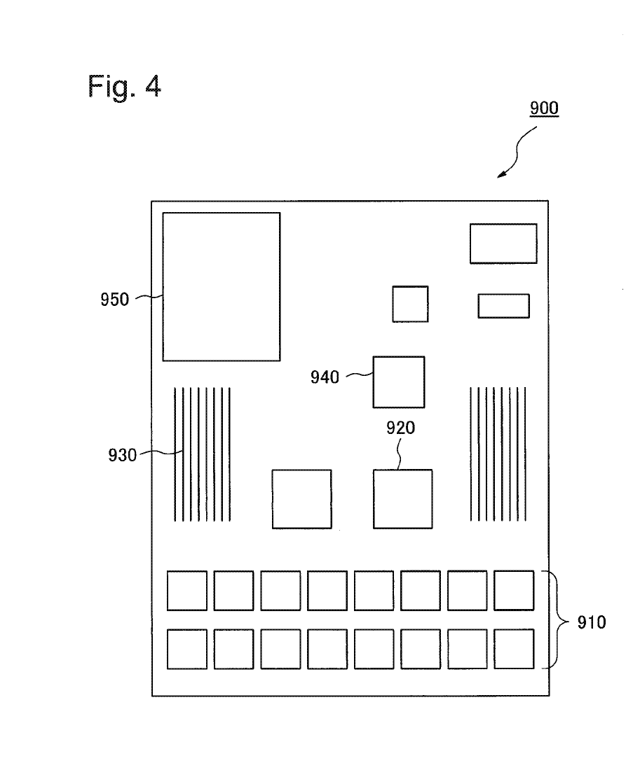

The second exemplary embodiment will be described. In this exemplary embodiment, a cooling device of a phase change cooling system is applied to a 1U server. FIG. 3 indicates a top view showing an internal configuration of a server according to this exemplary embodiment. As a comparison, a top view showing an internal configuration of a related server to which an air cooling system has been applied is shown in FIG. 4.

In FIG. 3, the server 100 of a phase change cooling system according to this exemplary embodiment includes two pieces of cooling device 110, a series of pieces of fan 120, a CPU 130 which is not illustrated in FIG. 3, a heat generating component 140, a memory 150, a power supply 160, other electronic components, wiring and the like. In FIG. 3, each of the two pieces of cooling device 110 has a vaporizer 111, a steam pipe 112, a liquid pipe 113, a condenser 114 and a refrigerant 115 that is not illustrated in FIG. 3.

In the server 100 according to this exemplary embodiment, the CPU 130 radiates heat when operating, and is cooled by the cooling device 110. The heat generating component 140 and the power supply 160 generate heat when operating, and cooled by a cooling wind which is delivered from the fan 120.

On the other hand, in FIG. 4, the related server 900 of an air cooling system includes a fan 910, a CPU 920, a memory 930, a heat generating component 940, a power supply 950, other electronic components, wiring and the like. In the server 900 of FIG. 4, all of the CPU 920, the heat generating component 940 and the power supply 950 are cooled by a cooling wind delivered from the fan 910. Here, in order to improve a cooling capacity, a double-barreled fan 910 is arranged in the server 900 of an air cooling system.

When the server 100 equipped with the cooling device 110 of a phase change cooling system shown in FIG. 3 and the server 900 of an air cooling system shown in FIG. 4 are compared, the server 100 shown in FIG. 3 is obtained by arranging, in the server 900 shown in FIG. 4, the condenser 114 in a space that becomes available by substituting the one-barreled fan 120 for the two-barreled fan 910. Furthermore, by arranging the vaporizer 111 in a position over the CPU 920, and connecting the vaporizer 111 and the condenser 114 by the steam pipe 112 and the liquid pipe 113, the server 100 shown in FIG. 3 is obtained.

That is, the cooling device 110 of a phase change cooling system according to this exemplary embodiment can be arranged in the fan 910 of the related server 900 of an air cooling system by just making the occupation area of the fan 910 small without performing large layout changes about other components.

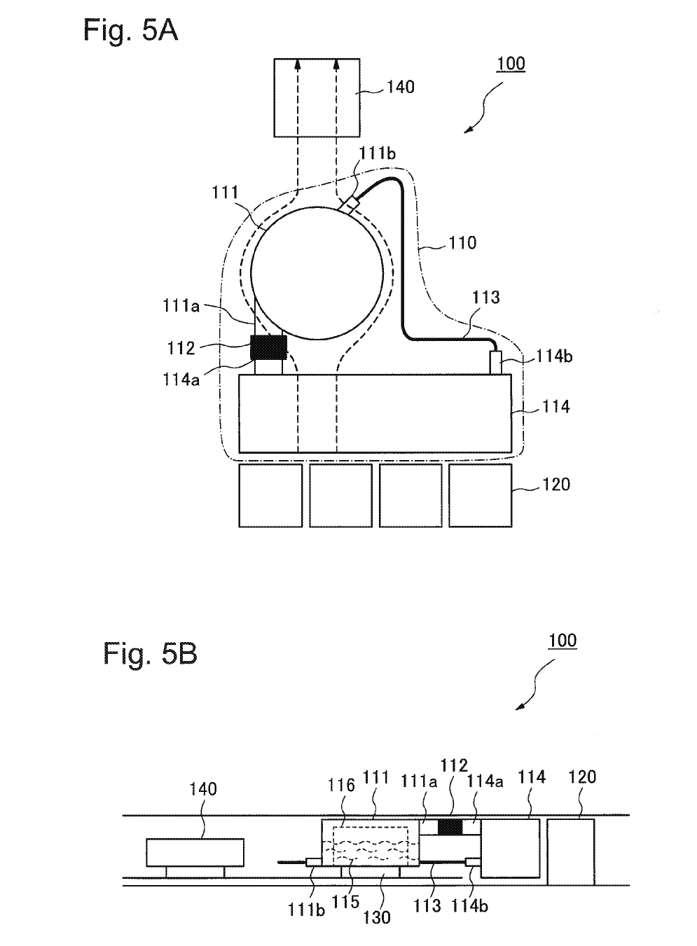

The server 100 according to this exemplary embodiment will be described using FIG. 3 and FIG. 5. FIG. 5A is a top view showing part of an internal configuration of the server 100 shown in FIG. 3, and FIG. 5B a perspective side views.

The cooling device 110 cools the CPU 130. The fan 120 cools the condenser 120 of the cooling device 110, the heat generating component 140 and the power supply 160. The cooling device 110 and the fan 120 will be described later.

The CPU 130 carries out various operations by reading a program or the like stored in the memory 150. The CPU 130 is formed by a semiconductor and the like, and generates heat along with its operations. The CPU 130 is cooled by the cooling device 110.

The heat generating component 140 is a component which generates heat along with its operations, and is a chipset or the like such as Northbridge. In FIG. 3 and FIG. 5, the heat generating component 140 is arranged at a lower portion in the side opposite to the condenser 114 when seen from the vaporizer 111. The heat generating component 140 is cooled by a cooling wind that is delivered from the fan 120, passes between the plate-like fins of the condenser 114, and guided to the side behind the vaporizer 111 along the side face of a curved surface shape of the vaporizer 111.

The memory 150 stores various kinds of information such as a program. In FIG. 3, a plurality of pieces of memory 150 are arranged in a direction parallel to the flowing direction of the cooling wind. As a result, a cooling wind which is delivered from the fan 120 and does not pass the vaporizer 111 passes the memory 150 and reaches the power supply 160.

The power supply 160 supplies electric power to each part of the server 100. In this exemplary embodiment, the power supply 160 is cooled by a cooling wind which is delivered from the fan 120 and passes the memory 150.

Next, the cooling device 110 and the fan 120 according to this exemplary embodiment will be described in detail.

The vaporizer 111 is arranged on the CPU 130, and houses a plurality of pieces of fin 116 and the refrigerant 115 in its interior. The vaporizer 111 includes a steam outlet head 111a for connecting the steam pipe 112, and a liquid inlet head 111b for connecting the liquid pipe 113. The vaporizer 111 cools the CPU 130 by absorbing heat released from the CPU 130. The vaporizer 111 makes heat released from the CPU 130 be heat-transferred to the refrigerant 115 of a liquid phase state stored inside the vaporizer 111 via the plurality of pieces of fin 116. By heat released from the CPU 130 being made to be heat-transferred to the refrigerant 115 of the liquid phase state, the refrigerant 115 performs a phase change to a vapor phase state from the liquid phase state.

In this exemplary embodiment, a height of the evaporative vessel which constitutes the vaporizer 111 is designed as a height that reaches near the upper surface of the chassis of the server 100 starting from the upper position of the CPU 130. Furthermore, the side face of an evaporative vessel is designed as a curved surface shape, such as a shape that widens smoothly once toward the direction of the heat generating component 140 starting from the fan 120 side, and then narrows smoothly. In this exemplary embodiment, the evaporative vessel is formed into a cylindrical shape having a height that reaches near the upper surface of the chassis of the server 100 when the vaporizer 111 is arranged on the CPU 130.

By arranging the vaporizer 111 near the upper surface of the chassis of the server 100, a cooling wind which flows to the backward passing the upper surface of the vaporizer 111 can be suppressed. By forming the side face of the evaporative vessel of the vaporizer 111 into a curved surface shape, it is possible to prevent a cooling wind which has reached the vaporizer 111 from being detached from the side face of the evaporative vessel, and to guide it to the side behind the vaporizer 111 along the side face without disturbing the flow.

The steam pipe 112 connects the vaporizer 111 and the condenser 114. The refrigerant 115 that has become a vapor phase state in the vaporizer 111 passes the steam pipe 112, and is transported to the condenser 114.

The liquid pipe 113 connects the condenser 114 and the vaporizer 111. The refrigerant 115 that has become a liquid phase state in the condenser 114 passes the liquid pipe 113, and is transported to the vaporizer 111 again.

The condenser 114 has a steam inlet head 114a for connecting the steam pipe 112, a liquid outlet head 114b for connecting a liquid pipe 113 and a plurality of tubular bodies which are not illustrated and plate-like fins which are stacked along the lengthwise direction of this tubular body. In the condenser 114, the plurality of tubular bodies which are not illustrated are arranged in parallel with each other in a direction perpendicular to the direction of the cooling wind delivered from the fan 120. By the refrigerant 115 of the vapor phase state passing in the tubular bodies of the condenser 114, heat of the refrigerant 115 is radiated via plate-like fins, and the refrigerant 115 of the vapor phase state is cooled. A cooling wind which has cooled plate-like fins flows out into the backward of the condenser 114, that is, into the side of the vaporizer 111 and the memory 150 just as it is. By heat of the refrigerant 115 being radiated, the refrigerant 115 changes its phase to a liquid phase state from a vapor phase state.

The refrigerant 115 is a medium having low-boiling points. As the refrigerant 115, an organic refrigerant such as HFC (hydrofluorocarbon) and HFE (hydro-fluoro ether) can be applied. The refrigerant 115 performs heat-absorption of heat of the CPU 130, and changes its phase to a vapor phase state from a liquid phase state in the vaporizer 111. The refrigerant 115 of the vapor phase state is transported to the condenser 114 via the steam pipe 112. Further, the refrigerant 115 condenses due to heat being transported to outside air in the condenser 114, and changes its phase to a liquid phase state from the vapor phase state. The refrigerant 115 of the liquid phase state is transported to the vaporizer 111 again via the liquid pipe 113.

In the cooling device 110 configured as above, the refrigerant 115 keeps circulating in the cooling device 110 without using a pump, and cools the CPU 130 by radiating heat generated in the CPU 130 to outside air.

The fan 120 is arranged facing the condenser 114 of the cooling device 110, and mainly cools the condenser 114 by air by delivering a cooling wind to the condenser 114. A cooling wind released from the fan 120 passes between the plate-like fins of the condenser 114 which are stacked, and flows into a space behind the condenser 114. In FIG. 3, in an area besides the area where the vaporizer 111 is arranged, a cooling wind which has flowed out to a space behind the condenser 114 passes through the memory 150 arranged behind the condenser 114 and cools the power supply 160.

On the other hand, in FIG. 5A, part of the cooling wind which has flowed out to a space behind the condenser 114 reaches the vaporizer 111. Then, because the evaporative vessel of the vaporizer 111 has been formed into a cylindrical shape having a height that reaches near the upper surface of the chassis of the server 100, a cooling wind which has reached the vaporizer 111 flows along the side face of the evaporative vessel and is guided to the side behind the vaporizer 111 without passing a space over the vaporizer 111. The cooling wind guided to the side behind the vaporizer 111 reaches the heat generating component 140 arranged behind the vaporizer 111 and cools the heat generating component 140. A flow of a cooling wind at that time is shown in FIG. 5A by a dotted line.

As above, the cooling device 110 according to this exemplary embodiment and the server 100 using that can change the related server 900 of an air cooling system to a server of a phase change cooling system by just replacing part of fans by a condenser without performing other large layout changes.

Further, by designing, in the cooling device 110 according to this exemplary embodiment and the server 100 using that, the height of the evaporative vessel of the vaporizer 111 as a height that reaches near the upper surface of the chassis of the server 100, and designing a side face of the evaporative vessel in a curved surface shape such as a shape that widens toward the direction of the heat generating component 140 smoothly once from the side of the fan 120 and then narrows smoothly, for example, the heat generating component 140 arranged at the back of the vaporizer 111 can be cooled efficiently using a cooling wind which has been delivered from the fan 120.

Accordingly, the cooling device 110 according to this exemplary embodiment and the server 100 using that can improve, in a thin type server such as a 1U server, the cooling efficiency of a 1U server as a whole only by arranging the condenser 114 in a space that becomes available by substituting the one-barreled fan 120 of a refrigerant circulation type for the two-barreled fan 910 of an air cooling system.

Here, as shown in FIG. 5A and FIG. 5B, it is desirable to arrange the steam outlet head 111a and the liquid inlet head 111b of the vaporizer 111 in a manner opposite to each other. By arranging the steam outlet head 111a and the liquid inlet head 111b in a manner opposite to each other, the refrigerant 115 can be made circulate through inside the vaporizer 111 smoothly, and the cooling efficiency of the cooling device 110 can be improved.

### Modified Example of Second Exemplary Embodiment

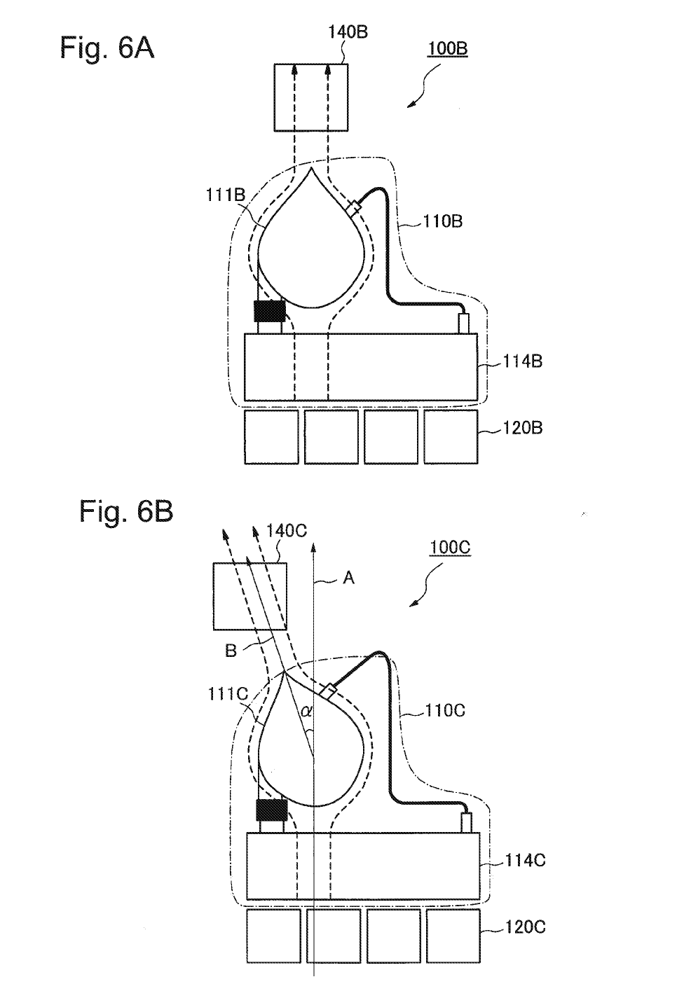

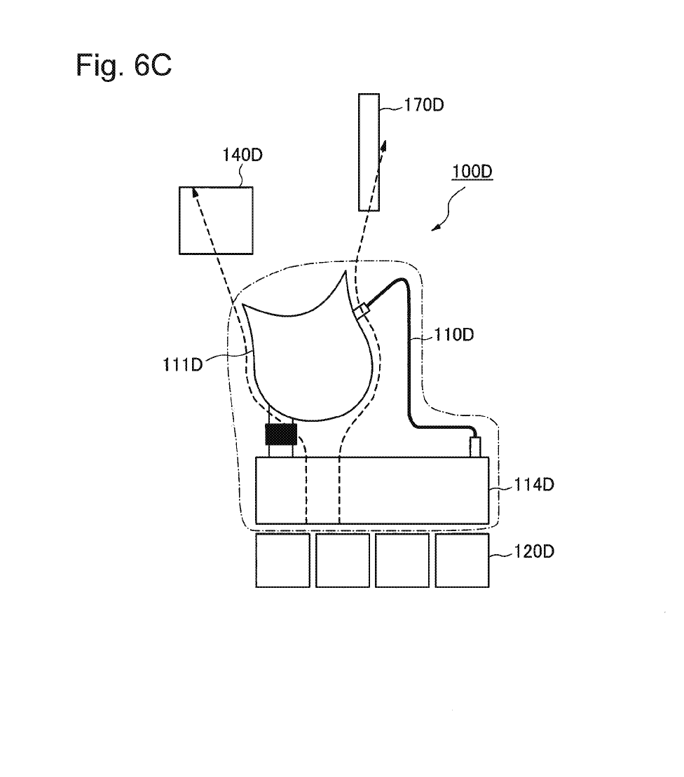

A modified example of the second exemplary embodiment will be described. Top views showing part of the internal configuration of a server according to this exemplary embodiment are shown in FIG. 6A, FIG. 6B and FIG. 6C.

First, the server 100B shown in FIG. 6A will be described. In FIG. 6A, the evaporative vessel of a vaporizer 111B has a height that reaches near the upper surface of the chassis of the server 100B, and the cross section of the evaporative vessel is formed into a drop shape made by joining streamline shapes. A streamline is a curve line which makes the fluid resistance due to detachment minimum. By forming the cross-sectional shape of the evaporative vessel into the drop shape, a cooling wind which has reached the vaporizer 111B can be made to flow into the side behind the vaporizer 111B in a state that turbulence is made minimal, that is, in a state that decline of an air volume is suppressed to a minimum.

A flow of a cooling wind at that time will be described. A flow of a cooling wind is shown in FIG. 6A in a dotted line. In FIG. 6A, a cooling wind which has been delivered from a fan 120B, passed between the fins of a condenser 114B and reached the vaporizer 111B is guided to the side behind the vaporizer 111B along the streamline shape of the evaporative vessel and reaches a heat generating component 140B arranged at the back of the vaporizer 111B. Furthermore, because the evaporative vessel is formed up to near the upper surface of the chassis of the server 100B, a cooling wind which flows out passing the upper surface of the condenser 114B can be suppressed. Accordingly, the heat generating component 140B can be cooled efficiently using a cooling wind which has been delivered from the fan 120B.

Next, the server 100C shown in FIG. 6B will be described. In FIG. 6B, a heat generating component 140C is arranged in a direction (hereinafter, it is described as B direction) which forms an angle α to the arrangement direction (hereinafter, it is described as A direction.) of a fan 120C, a condenser 114C and a vaporizer 111C when seen from the vaporizer 111C.

In FIG. 6B, the vaporizer 111C is made by rotating the condenser 111B shown in FIG. 6A horizontally counterclockwise so that the straight line which ties the center of the drop shape and the joint forms angle α. That is, the side face of the evaporative vessel of the vaporizer 111C is widened in the B direction smoothly once and then narrows smoothly. Furthermore, the evaporative vessel is formed with a height that reaches near the upper surface of the chassis of the server 100C.

A flow of a cooling wind at that time will be described. A flow of a cooling wind is shown in FIG. 6B in a dotted line. In FIG. 6B, a cooling wind which has been delivered from the fan 120C passes between the fins of the condenser 114C and reaches the vaporizer 111C. At that time, the cooling wind is flowing toward the A direction. Then, the cooling wind of the A direction is bent along the streamline shape of the evaporative vessel, and the flow changes toward the B direction. That is, the cooling wind is guided toward the B direction from the vaporizer 111C, and reaches the heat generating component 140C. Meanwhile, because the evaporative vessel is formed with a height that reaches near the upper surface of the chassis of the server 100C, a cooling wind which flows out passing the upper surface of the vaporizer 111C can be suppressed. Accordingly, the heat generating component 140C can be cooled efficiently using a cooling wind which has been delivered from the fan 120C.

The server 100D shown in FIG. 6C will be described. In FIG. 6C, the evaporative vessel of a vaporizer 111D is formed with a cross-sectional shape of a streamline shape having two joints and with a height that reaches near the upper surface of the chassis of the server 100D. In addition, in FIG. 6C, there is arranged a heat generating component 140D on an extended line of a straight line which connects one joint and the center of the evaporative vessel, and there is arranged a PCI (Peripheral Component Interconnect) slot 170D, for example, on an extended line of a straight line which connects the other joint and the center. There is attached a PCI card to the PCI slot 170D, and the PCI slot 170D connects the PCI card and the motherboard of the server 100D electrically. Heat occurs associated with PCI card operating.

A flow of a cooling wind at that time will be described. A flow of a cooling wind is shown in FIG. 6C in a dotted line. In FIG. 6C, a cooling wind, which has been delivered from a fan 120D, passed a condenser 114D and reached the vaporizer 111D, is divided into two branches along a streamline shape-like side face of the evaporative vessel and flows to the side of the heat generating component 140D and the side of the PCI slot 170D. Because the evaporative vessel is formed with a height that reaches near the upper surface of the chassis of the server 100D, a cooling wind which flows out passing the upper surface of the vaporizer 111D is suppressed. Accordingly, the heat generating component 140D and the PCI slot 170D which are arranged in different directions behind the vaporizer 111D can be cooled efficiently using a cooling wind which has been delivered from the fan 120D and reached the vaporizer 111D.

As above, in the cooling device according to this exemplary embodiment and the server using the same, the evaporative vessel has a height that reaches near the upper surface of the chassis of the server and its cross-sectional shape is formed with a drop shape made by joining streamline shapes. Because a streamline shape is a curve line which makes fluid resistance due to detachment minimal, a cooling wind can be led to the side behind the vaporizer efficiently in a manner keeping a wind speed while suppressing occurrence of detachment and a turbulent flow from the side face of the evaporative vessel in a minimum, and thus components arranged behind the vaporizer can be cooled. That is, even when a cooling device of a refrigerant circulation type is mounted on a thin type server such as a 1U server, the cooling efficiency of the 1U server as a whole can be improved.

Meanwhile when a refrigerant circulation system is substituted for an air cooling system in a thin type server, only part of a plurality of cooling fans is needed to be replaced by a cooling device of a refrigerant circulation type according to this exemplary embodiment, and a layout change of each component in the server is unnecessary.

In addition, a flow of a cooling wind which has reached a vaporizer can be bent into a desired direction by making the side face of an evaporative vessel be a drop shape made by joining streamline shapes and turning the joint to a desired direction. Accordingly, a cooling wind which has been delivered from a fan and reached a vaporizer can be made to flow toward the side of a heat generating component easily. Further, by forming the side face of the evaporative vessel into a shape made by joining streamline shapes at a plurality of points, a plurality of heat generating components which are arranged in different directions behind the vaporizer can be cooled simultaneously using a cooling wind which has reached the vaporizer.

Here, in the cooling device according to this exemplary embodiment and the server using that, it is desirable to arrange a steam outlet head and a liquid inlet head of the vaporizer in opposite positions from each other.

### Third Exemplary Embodiment

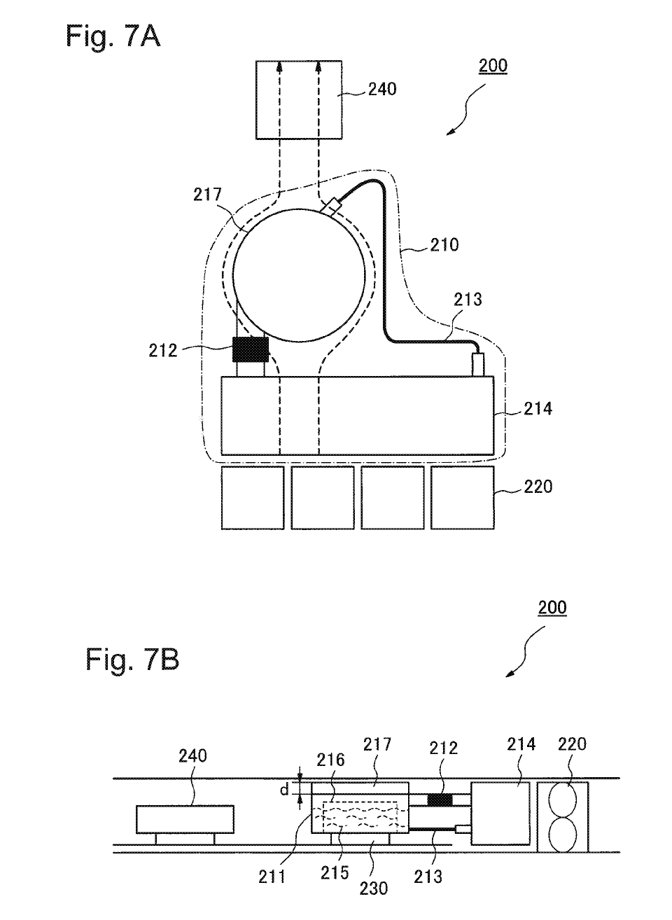

The third exemplary embodiment will be described. FIG. 7A indicates a top view showing part of an internal configuration of a server according to this exemplary embodiment, and FIG. 7B shows its perspective side view. In FIG. 7A and FIG. 7B, the server 200 according to this exemplary embodiment includes a cooling device 210, a fan 220, a CPU 230 and a heat generating component 240. The cooling device 210 includes a vaporizer 211, a steam pipe 212, a liquid pipe 213, a condenser 214, a refrigerant 215 and a flow path suppression member 217.

The fan 220, the CPU 230, the heat generating component 240, the steam pipe 212, the liquid pipe 213, the condenser 214 and the refrigerant 215 have the same functions as the fan 120, the CPU 130, the heat generating component 140, the steam pipe 112, the liquid pipe 113, the condenser 114 and the refrigerant 115 described in the second exemplary embodiment. Hereinafter, description will be made centering on parts different from the server 100 according to the second exemplary embodiment.

The side face of an evaporative vessel which constitutes the vaporizer 211 is formed with a curved surface shape such as a shape that is widened toward the direction of the heat generating component 240 from the side of the fan 220 smoothly once and then narrows smoothly. In this exemplary embodiment, the vaporizer 211 is formed into a cylindrical shape.

A flow path suppression member 217 is a plate-like body of height d. The flow path suppression member 217 can be formed using resin or the like. In this exemplary embodiment, the flow path suppression member 217 is formed into a columnar form of height d having the same cross-sectional shapes as the vaporizer 211. When arranging the vaporizer 211 on the CPU 230 and arranging the flow path suppression member 217 on the vaporizer 211, the height d is set as a height that the upper surface of the flow path suppression member 217 reaches near the upper surface of the chassis of the server 200.

By arranging the flow path suppression member 217 of height d on the vaporizer 211, a cooling wind which flows toward the backward passing the upper surface of the flow path suppression member 217 can be suppressed. Also, by forming the evaporative vessel and the flow path suppression member 217 into cylindrical shapes, a cooling wind which has reached the vaporizer 211 and the flow path suppression member 217 is led to the side behind the vaporizer 211 and the flow path suppression member 217 along the side faces of the evaporative vessel and the flow path suppression member 217.

As above, in the cooling device 210 according to this exemplary embodiment and the server 200 using that, the side faces of the evaporative vessel and the flow path suppression member 217 are formed as a curved surface shape such as a shape that widens toward the direction of the heat generating component 240 from the side of the fan 220 smoothly once and then narrows smoothly. Furthermore, height d of the flow path suppression member 217 is set to a height by which the upper surface of the flow path suppression member 217 reaches near the upper surface of the chassis of the server 200 when arrangement of the CPU 230, the vaporizer 211 and the flow path suppression member 217 is made in a stacked manner. In this case, the heat generating component 240 arranged behind the vaporizer 211 can be cooled efficiently using a cooling wind which has been delivered from the fan 220. That is, even when the cooling device 210 of a refrigerant circulation type is mounted on the thin type server 200 such as a 1U server, the cooling efficiency of the server 200 as a whole can be improved.

Meanwhile, when a refrigerant circulation system is substituted for an air cooling system in a thin type server, only part of a plurality of cooling fans is needed to be replaced by the condenser 214, and a layout change of each component in the server is unnecessary.

In addition, in a case where the vaporizer 211 and the flow path suppression member 217 of height d are used together, when CPUs of different heights are used, or when the heights of servers differ from each other, the vaporizer 211 can be used in common by changing height d of the flow path suppression member 217 according to that. Accordingly, a vaporizer does not need to be prepared for each CPU or server, and thus the cost of the cooling device 210 and the server 200 can be made to be low.

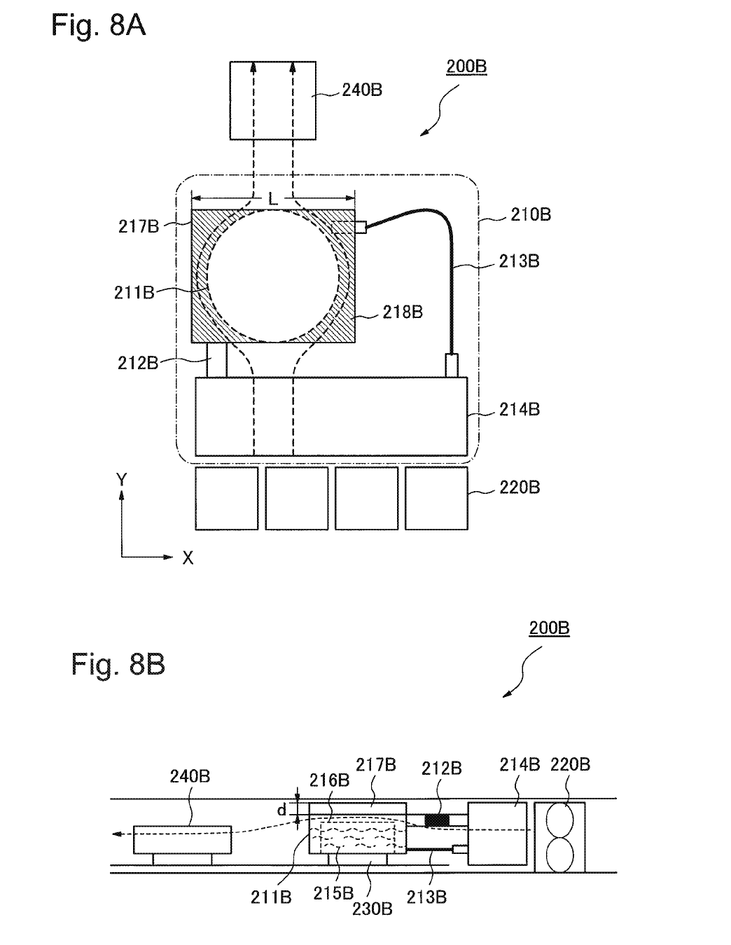

Here, in the above-mentioned exemplary embodiment, although the cross-sectional shape of the flow path suppression member 217 is made to be the same as the cross-sectional shape of the evaporative vessel of the vaporizer 211, it is not limited to this. FIG. 8A indicates a top view showing part of the internal configuration of a server in which a flow path suppression member having another cross-sectional shape is arranged, and FIG. 8B shows its perspective side view.

In FIG. 8A and FIG. 8B, the server 200B has a flow path suppression member 217B of a rectangular parallelepiped shape. When supposing that the direction of a flow of a cooling wind is y-direction and the arrangement direction of pieces of fan 220B is x-direction, length of a side of the flow path suppression member 217B in the x-direction is set to L and the height is sets to d.

Height d is set to a height by which the upper surface of the flow path suppression member 217B reaches near the upper surface of the chassis of the server 200B when arranging a vaporizer 211B on a CPU 230B and arranging the flow path suppression member 217B on the vaporizer 211B. By arranging the flow path suppression member 217B of height d on the vaporizer 211B, a cooling wind which flows to the backward passing the upper surface of the flow path suppression member 217B can be suppressed.

On the other hand, length L is set to a numerical value larger than the diameter of the vaporizer 211B. Accordingly, when the flow path suppression member 217B is arranged on the vaporizer 211B, part of the flow path suppression member 217B projects in the x-direction from the vaporizer 211B. A portion of the flow path suppression member 217B projecting from the vaporizer 211B (hereinafter, it is described as a projecting portion 218B) is shown in FIG. 8A in a slant line. A cooling wind which has reached the flow path suppression member 217B and the vaporizer 211B flows under the projecting portion 218B of the flow path suppression member 217B since the flow path suppression member 217B is equipped with the projecting portion 218B. Meanwhile, although the length of the flow path suppression member 217B of a side in the y-direction is formed as a size equal to the diameter of the vaporizer 211B as shown in FIG. 8A, it is not limited to this.

A flow of a cooling wind at that time will be described. A flow of a cooling wind is shown in FIG. 8A and FIG. 8B in a dotted line. In FIG. 8A and FIG. 8B, a cooling wind which has been delivered from the fan 220B, passed a condenser 214B and reached the vaporizer 211B and the flow path suppression member 217B goes around to the backward along the side face of an evaporative vessel and is led by the projecting portion 218B of the flow path suppression member 217B downward. Then, the cooling wind led behind the vaporizer 211B downwardly reaches a heat generating component 240B and cools the heat generating component 240B.

As above, in the server 200B equipped with a cooling device 210B according to this exemplary embodiment, the flow path suppression member 217B of height d equipped with the projecting portion 218B is arranged on the vaporizer 211B. In this case, by setting height d of the flow path suppression member 217B according to the heights of the server 200B and the CPU 230B, the vaporizer 211B can be used in common. Further, because the flow path suppression member 217B is equipped with the projecting portion 218B, a cooling wind which has reached the vaporizer 211B and the flow path suppression member 217B is led below the projecting portion 218B of the flow path suppression member 217B. Accordingly, the heat generating component 240B of a low height which is arranged on the substrate at the back of the vaporizer 211B can be cooled efficiently using a cooling wind which is delivered from the fan 220B.

Here, it is possible to form part of the under surface of the projecting portion 218B of the flow path suppression member 217B into a concave shape, or a shape inclining downward. In this case, a cooling wind is able to be led downward furthermore.

### Fourth Exemplary Embodiment

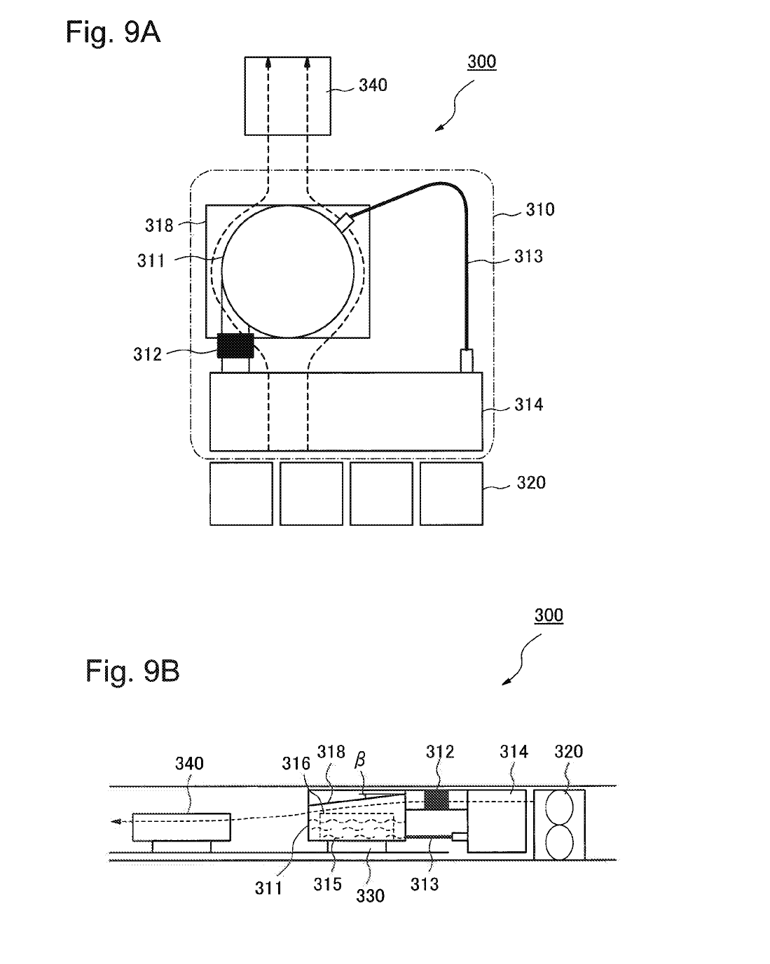

The fourth exemplary embodiment will be described. FIG. 9A indicates a top view showing part of the internal configuration of a server according to this exemplary embodiment, and FIG. 9B shows its perspective side view. In FIG. 9A and FIG. 9B, the server 300 according to this exemplary embodiment includes a cooling device 310, a fan 320, a CPU 330 and a heat generating component 340. The cooling device 310 includes a vaporizer 311, a steam pipe 312, a liquid pipe 313, a condenser 314, a refrigerant 315 and a straightening member 318.

A point that the server 300 according to this exemplary embodiment is different from the server 100 according to the second exemplary embodiment is that the straightening member 318 is arranged around the vaporizer 311. Hereinafter, description will be made focusing on a point different from the server 100 described in the second exemplary embodiment.

The straightening member 318 is arranged in a periphery of the evaporative vessel of which the vaporizer 311 is composed, and is formed of a tabular member, for example. As shown in FIG. 9B, the straightening member 318 is fastened to the vaporizer 311 in a state being inclined downward by inclined angle β from the upper end of the vaporizer 311 in the side of the condenser 314.

A flow of a cooling wind at that time will be described. A flow of a cooling wind is shown in FIG. 9A and FIG. 9B in a dotted line. In FIG. 9A and FIG. 9B, a cooling wind which has been delivered from the fan 320, passed between the fins of the condenser 314 and reached the vaporizer 311 flows toward the side behind the vaporizer 311 along the under surface of the straightening member 318 and the side face of the evaporative vessel. Here, because the straightening member 318 is fastened in a state inclining downward, the cooling wind which has reached the vaporizer 311 flows into the side behind the vaporizer 311 downward. The cooling wind led to the side behind the vaporizer 311 downward reaches the heat generating component 340 of a low height arranged in a lower position at the back of the vaporizer 311, and cools the heat generating component 340.

In addition, a cooling wind which flows toward the backward passing the upper surfaces of the vaporizer 311 and the straightening member 318 can be suppressed because the evaporative vessel of the vaporizer 311 is formed with a height that reaches near the upper surface of the chassis of the server 300 and the straightening member 318 is fastened to the upper end of the vaporizer 311 in the side of the condenser 314. Accordingly, the heat generating component 340 can be cooled efficiently.

As above, by fastening the straightening member 318 to the vaporizer 311 in the cooling device 310 according to this exemplary embodiment and the server 300 using that, the heat generating component 340 of a low height which is arranged in a downward position at the back of the vaporizer 311 can be cooled efficiently using a cooling wind which is delivered from the fan 320. That is, even when the cooling device 310 of a refrigerant circulation system is mounted on the thin type server 300 such as a 1U server, the cooling efficiency of the server 300 as a whole can be improved.

Meanwhile, when, in a thin type server, a refrigerant circulation system is substituted for an air cooling system, only part of a plurality of cooling fans is needed to be replaced by the condenser 314, and a layout change of each of the other components in the server is unnecessary.

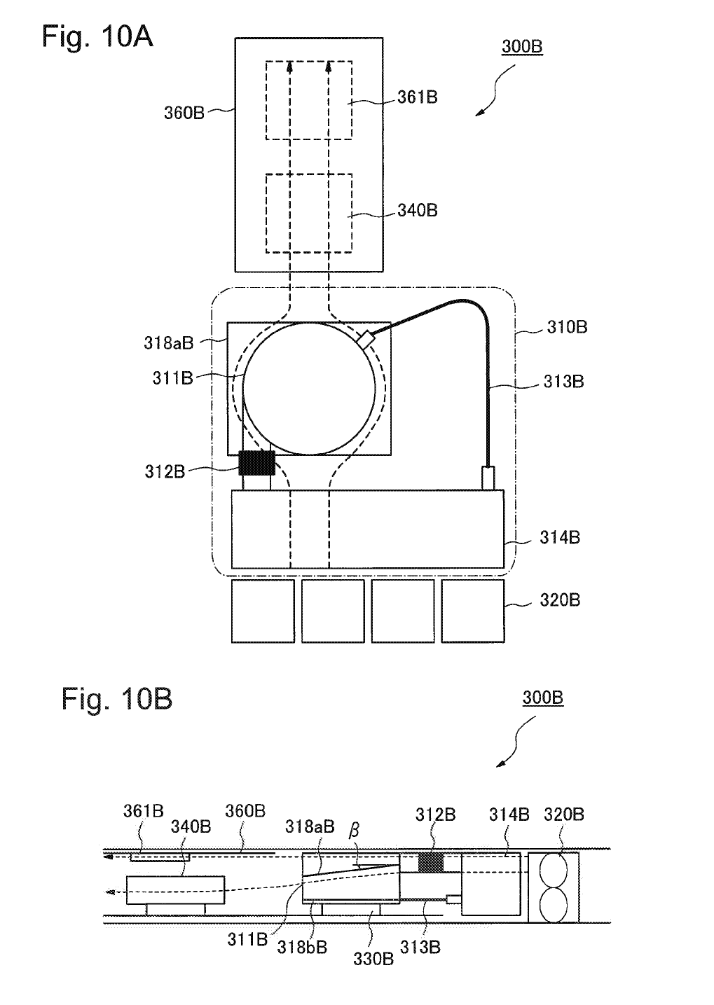

Here, a plurality of straightening members can be arranged in a vaporizer. FIG. 10A indicates a top view showing part of an internal configuration of a server when arranging two straightening members in a vaporizer, and FIG. 10B shows its side view.

In FIG. 10A and FIG. 10B, the server 300B according to this exemplary embodiment includes a cooling device 310B, a fan 320B, a CPU 330B, a heat generating component 340B and a PCI slot 360B. The cooling device 310B includes a vaporizer 311B, a steam pipe 312B, a liquid pipe 313B, a condenser 314B, the refrigerant 315 B, two straightening members 318aB and 318bB.

The heat generating component 340B is a component of a low height which generates heat with operations. In the PCI slot 360B, there is mounted a heat generating component such as a LSI (Large Scale Integration) 361B. As shown in FIG. 10B, the heat generating component 340B is arranged in a lower portion of the server 300B, and the PCI slot 360B is arranged in an upper portion of the server 300B.

The straightening members 318aB and 318bB are tabular members each having a hole for fitting the vaporizer 311B in its center, for example. In FIG. 10B, the straightening member 318aB is fastened to the vaporizer 311B in a state inclining downward by inclined angle β from a middle portion of the vaporizer 311. On the other hand, the straightening member 318bB is fastened horizontally under the straightening member 318aB of the vaporizer 311B.

A flow of a cooling wind at that time will be described. A flow of a cooling wind is shown in FIG. 10A and FIG. 10B in a thin dotted line. In FIG. 10A and FIG. 10B, part of a cooling wind which has been delivered from the fan 320B, passed between the fins of the condenser 314B and reached the vaporizer 311B is led toward the side behind the vaporizer 311B upwardly along the upper surface of the straightening member 318aB and the side face of the evaporative vessel. A cooling wind led toward the side behind the vaporizer 311B upwardly reaches the PCI slot 360B and cools the LSI 361B.

On the other hand, the remaining cooling wind is led toward the side behind the vaporizer 311B downward along the under surface of the straightening member 318aB, the upper surface of the straightening member 318bB and the side face of the evaporative vessel. The cooling wind led toward the side behind the vaporizer 311B downward reaches the heat generating component 340B, and cools the heat generating component 340B.

As above, by arranging two straightening members 318aB and 318bB in the vaporizer 311B in the cooling device 310B according to this exemplary embodiment and the server 300B using that, both of the heat generating component 340B arranged in a lower portion of the server 300B and the PCI slot 360B arranged in an upper portion of the server 300B can be cooled using a cooling wind which has reached the vaporizer 311B.

Meanwhile, the number of the straightening members arranged in a vaporizer is not limited to 1 or two. Also, a straightening member described in this exemplary embodiment and a flow path suppression member described in the third exemplary embodiment can be combined. Further, it is not limited to make a straightening member and a flow path suppression member be fastened to a cylindrical evaporative vessel. For example, it is possible to make a straightening member and a flow path suppression member be fastened to an evaporative vessel which is formed into a drop shape made by joining streamline shapes described in a modified example of the second exemplary embodiment, or into a truncated cone shape, or into a temple bell shape or the like.

Meanwhile, although the present invention has been described with reference to an exemplary embodiment, the present invention is not limited to the above-mentioned exemplary embodiments. Even if there is a change or the like in the design within the range that does not deviate from the point of this invention, it is included in this invention.

This application claims priority based on Japanese application Japanese Patent Application No. 2012-000077, filed on Jan. 4, 2012, the disclosure of which is incorporated herein in its entirety.

### INDUSTRIAL APPLICABILITY

The present invention can be applied to a component, equipment and a system in general having a heat generating member as well as a cooling device which cools the heat generating member in its interior.

### DESCRIPTION OF SYMBOL

10 Electronic equipment
20 Cooling device
21 Vaporizer
22 Condenser
23 Steam pipe
24 Liquid pipe
25 Refrigerant
26 Flow path suppression means
31 First heat generating member
32 Second heat generating member
40 Fan
90 Electronic equipment
91 First heat generating member
92 Second heat generating member
93 Fan
100, 200 and 300 Server
110, 210 and 310 Cooling device
111, 211 and 311 Vaporizer
112, 212 and 312 Steam pipe
113, 213 and 313 Liquid pipe
114, 214 and 314 Condenser
115, 215 and 315 Refrigerant
116, 216 and 316 Fin
217 Flow path suppression member
318 Straightening member
120, 220 and 320 Fan
130, 230 and 330 CPU
140, 240 and 340 Heat generating component
150 Memory
160 Power supply
900 Server
910 Cooling device
920 CPU
930 Memory
940 Heat generating component
950 Power supply

1. A cooling device to be arranged in a chassis having an upper surface, comprising:
a refrigerant;
a vaporizer including an evaporative vessel having a side face of a curved surface shape, and performing heat-absorption by making said refrigerant change a phase from a liquid phase state to a vapor phase state;
a condenser which performs heat-radiation by making said refrigerant change a phase from a vapor phase state to a liquid phase state;
a pipe to connect said vaporizer and said condenser; and
a flow path suppression part for suppressing a cooling wind flowing between an area over said evaporative vessel and said upper surface.

2. The cooling device according to claim 1, wherein
said evaporative vessel functions as said flow path suppression part and said evaporative vessel is formed with a height reaching near an upper surface of said chassis.

3. The cooling device according to claim 1, wherein
said flow path suppression part includes a flow path suppression member arranged in an area over said evaporative vessel, and said flow path suppression member is formed with a height reaching near an upper surface of said chassis, upon said flow path suppression member being arranged on said vaporizer.

4. The cooling device according to claim 3, wherein
said flow path suppression member has a projecting portion projecting from said evaporative vessel.

5. The cooling device according to claim 1, further comprising
a straightening member arranged in a periphery of said evaporative vessel.

6. The cooling device according to claim 5, wherein
said straightening member is a tabular member; and wherein
said tabular member is arranged in said periphery in a state being inclined from a horizontal direction.

7. The cooling device according to claim 1, wherein
said evaporative vessel has a circular cross-sectional shape.

8. The cooling device according to claim 1, wherein
said evaporative vessel has a cross-sectional shape of a drop shape made by joining streamline shapes.

9. The cooling device according to claim 1, wherein
said evaporative vessel has a cross-sectional shape made by joining streamline shapes at a plurality of positions.

10. The cooling device according to claim 1, wherein
said pipe includes a steam pipe to transport said refrigerant from said vaporizer to said condenser, and a liquid pipe to transport said refrigerant from said condenser to said vaporizer, wherein
said vaporizer includes a steam outlet head to connect said steam pipe and a liquid inlet head to connect said liquid pipe, and wherein
said steam outlet head and said liquid inlet head are arranged opposite to each other.

11. The cooling device according to claim 1, wherein
said condenser includes a tubular body to make said refrigerant flow in its interior, and a plurality of radiators arranged around said tubular body.

12. Electronic equipment, comprising:
a chassis having an upper surface;
a cooling device according to claim 1;
a first heat generating member and a second heat generating member, both generating heat along with their operations; and
a fan being arranged facing said condenser of said cooling device which delivers a cooling wind; wherein
said first heat generating member is arranged in an area under said evaporative vessel; and wherein
said second heat generating member is arranged in a direction along a curved-surface-shape side face of said evaporative vessel.

13. The electronic equipment according to claim 12, further comprising:
a third heat generating member; wherein
said evaporative vessel includes a cross-sectional shape having two joints made by joining a plurality of streamline shapes; wherein
said second heat generating member is arranged on an extended line of a straight line connecting a center of said evaporative vessel and one of said joints; and wherein
said third heat generating member is arranged on an extended line of a straight line connecting a center of said evaporative vessel and a different one of said joints.

14. A cooling device to be arranged in a chassis having an upper surface, comprising:
a refrigerant;
a vaporizer including an evaporative vessel having a side face of a curved surface shape, and performing heat-absorption by making said refrigerant change a phase from a liquid phase state to a vapor phase state;
a condenser which performs heat-radiation by making said refrigerant change a phase from a vapor phase state to a liquid phase state;
a pipe to connect said vaporizer and said condenser; and
a flow path suppression means for suppressing a cooling wind flowing between an area over said evaporative vessel and said upper surface.
